(19) United States
(12) Patent Application Publication
(10) Pub. No.: US 2020/0354826 A1
(43) Pub. Date: Nov. 12, 2020

(54) METHOD TO PRODUCE HIGH DENSITY DIAMOND LIKE CARBON THIN FILMS

(71) Applicant: INTEVAC, INC., Santa Clara, CA (US)

(72) Inventors: Samuel D. Harkness, IV, Albany, CA (US); Kentaro Takano, San Jose, CA (US); Jae Ha Choi, Pleasanton, CA (US)

(21) Appl. No.: 15/929,467

(22) Filed: May 4, 2020

Related U.S. Application Data
(60) Provisional application No. 62/845,041, filed on May 8, 2019.

(51) Int. Cl. C23C 14/34; C23C 14/06; C23C 14/58; C23C 14/50

(52) U.S. Cl. CPC C23C 14/34; C23C 14/505; C23C 14/5873; C23C 14/0611

(57) ABSTRACT

A method for forming a diamond-like carbon (DLC) coating on an article is provided, comprising: alternatingly performing a deposition process and an ashing process on the article a determined number of times, wherein during the deposition process the method proceeds by forming on the article a layer of DLC which includes graphitic sp² carbon and tetrahedral sp³ carbon, and during the ashing process the method proceeds by selectively etching the graphitic sp² carbon, wherein the determine number of time is configured to result in a designated overall thickness of the DLC coating.

### RELATED APPLICATIONS

This application claims priority benefit from U.S. Provisional Application 62/845,041, filed on May 8, 2019, the entire disclosure of which is incorporated herein by reference.

### BACKGROUND

### 1. Field

This disclosure relates generally to the field of substrate processing, especially to thin-film coating of articles with hard protective coat.

### 2. Related Art

Hard protective coating has been used to protect articles from wear during use and operation. For example, diamond-like carbon (DLC) coating has been used to protect machinery parts, gears, recordable disks of hard drives, etc. DLC exists in seven forms, wherein the hardness property is imparted mostly by sp³ hybridized carbon atoms. DLC is typically produced by processes in which high energy precursive carbons (e.g. in plasmas, in filtered cathodic arc deposition, in sputter deposition and in ion beam deposition) are rapidly cooled or quenched on relatively cold surfaces. In those cases, cubic and hexagonal lattices can be randomly intermixed, layer by atomic layer, because there is no time available for one of the crystalline geometries to grow at the expense of the other before the atoms are “frozen” in place in the material. The resulting films have a mix of sp² and sp³ carbon, the sp² rendering the coating softer, thereby in essence degrading the protective properties of the DLC coating.

Commercial methods of producing DLC coating result in a relatively large amount of sp² carbon, which has a lower density than the harder sp³. To increase the coating's hardness, the number of sp² carbon needs to be reduced. Accordingly, a need exists in the art for improved methods for forming DLC coating that has a high content of sp³ carbon.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Disclosed embodiments provide methods for producing high density DLC coating having high content of sp³ carbon. The disclosed methods are commercially viable as they rely on known processes for producing DLC to produce standard DLC film. However, the methods implement steps to extract the sp² carbon, thereby increasing the relative content of sp³ carbon and increasing the density of the resulting film.

In the disclosed embodiments a system for producing high density carbon is provided, wherein at least two processing stations are provided. One station forms standard DLC film while the other station extracts sp² carbon from the just produced film. The system is configured to form a high density DLC film by cycling the substrate repeatedly between the two stations until the desired film thickness is achieved.

Aspect of the disclosure include a method for forming a diamond-like carbon (DLC) coating on an article, comprising: alternatingly performing a deposition process and an ashing process on the article a determined number of times, wherein during the deposition process the method proceeds by forming on the article a layer of DLC which includes graphitic sp² carbon and tetrahedral sp³ carbon, and during the ashing process the method proceeds by selectively etching the graphitic sp² carbon, wherein the determine number of time is configured to result in a designated overall thickness of the DLC coating. The deposition process may be performed by sustaining plasma in a sputtering source. The plasma may be ignited and sustained in an argon environment within the sputtering source at a pressure of less than 1000 mPa. The process may include a preclean step of etching the article prior to alternatingly performing the deposition process and the ashing process. Etching the article may be performed by immersing the article in plasma maintained by at least one of argon and oxygen gas. At each step of forming a DLC layer, an amount of from 0.5 mg/m² to 2 mg/m² of carbon may be deposited on the article.

In further aspects, a method for forming a diamond-like carbon (DLC) coating on a substrate is provided, comprising: loading the substrate onto a substrate holder; repeatedly transporting the substrate on the holder between a carbon deposition module and a carbon etching module a predetermined number of times, and at the carbon deposition module forming a layer of carbon on the substrate and at the etching module partially etching the layer of carbon; wherein the predetermined number of times is configured to result in a designated total thickness of DLC coating. In each step of forming a layer of carbon an amount of carbon of from 0.5 mg/m² to 2 mg/m² is deposited. Partially etching the substrate may include immersing the substrate in oxygen plasma. Transporting the substrate may include rotating a turntable or linearly transporting the substrate holder.

In other aspects, a system for forming a diamond-like carbon (DLC) coating, is provided, comprising: a turntable for supporting at least one article; at least one carbon deposition module having a graphite target and positioned on an arc of the turntable; at least one ashing module positioned on an arc of the turntable; an argon gas source delivering argon gas to the at least one carbon deposition module; and an oxygen gas source delivering oxygen gas to the ashing module. The system may have one carbon deposition module and one ashing module positioned at 180 degrees separation around the turntable. Alternatively, the system may have a plurality of carbon deposition modules and a plurality of ashing module arranged around the turntable in an interlaced manner.

Also, in some aspects a system for forming a diamond-like coating (DLC) is provided, comprising: a loadlock; a linear array of processing modules; a linear track traversing the loadlock and the linear array of processing modules; a plurality of substrate carriers transported on the linear track; wherein the linear array of processing module comprises a plurality of sputtering modules each having a graphite target and a plurality of etching modules each connected to an oxygen source, wherein the plurality of sputtering modules and plurality of etching modules are interlaced to form the linear array. In an aspect, each sputtering module is attached directly to two etch modules, one on each side thereof, and each etch module is directly attached to at least one sputtering module, whereby the first and last modules are etch modules.

Other aspects and features of the invention would be apparent from the detailed description, which is made with reference to the following drawings. It should be appreciated that the detailed description and the drawings provides various non-limiting examples of various embodiments of the invention, which is defined by the appended claims.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a system for forming DLC coating according to an embodiment.

FIG. 2 illustrates an example of a linear system for forming a DLC coating, according to one embodiment, while FIG. 2A illustrates an example of a substrate carrier that may be used in the embodiment of FIG. 2.

FIG. 3 illustrate an embodiment of a processing module that may be used in the embodiment of FIG. 2.

### DETAILED DESCRIPTION

Embodiments of the inventive system and method for fabricating DLC coating will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

Disclosed embodiments may be implemented using one processing chamber having two processing modules or two processing chambers with vacuumed transport in between them. The system may be circular or linear. The system may be configured to shuttle one substrate between the two processing modules, or to handle two or more substrates simultaneously, such that when one substrate is in the deposition side, the other substrate is in the etch side.

In disclosed embodiments, a DLC layer comprising a mix of bonding arrangements including graphitic sp² carbon and tetrahedral sp³ carbon is deposited to a nanometer scale thickness, e.g., a few nanometers thick or a few tens of nanometers thick. The deposited DLC layer is then subsequently subjected to a reactive environment of radicals that chemically etch a portion of the freshly deposited material. The deposition process configured to maximize the amount of resultant sp³ bonded carbon while etch process is configured to maximize removal of graphitic sp². At the deposition station, this can entail the use of a variety of film fabrication methods, including physical and chemical vapor deposition techniques. During the etch cycle, use is made of the selectivity for graphitic material relative to that which is tetrahedral bonded. For example, etching by primarily oxygen radicals would selectively etch the sp² material. Once optimized for composition, the process can be iterated in multiples to generate films of a desired thickness.

In the prior art it has been known that ion bombardment and filtering of ions from neutrals are essential to the formation of high density tetrahedral amorphous carbon (ta-C). However, coupling filter assemblies that require large electromagnetic currents to force ions through a shaped pattern that the neutrals cannot follow renders such systems impractical. Moreover, the relatively low ion fraction achieved through such filtering renders such systems commercially unviable. Conversely, in disclosed embodiments the etch process is utilized as a form of filter, wherein the carbon film exposed to etch is preferentially etched locally where a higher concentration of graphite material is found. In so doing, the film is enriched in sp³ carbon and thereby implementing a filter at the film level.

Plasma ashing is well known process used in the semiconductor industry to remove photoresist from substrates. The plasma is used to generate reactive species, such as oxygen and fluorine, which combine with the photoresist to form ash that is removed with a vacuum pump. The process of plasma ashing may be beneficially used to preferentially remove the graphitic sp² from a nano-scale layer of DLC coating, thereby retaining the dense sp³ within the film. The ashing process may be performed using a remote plasma source, although it is found that for best results the substrate should be immersed in the plasma.

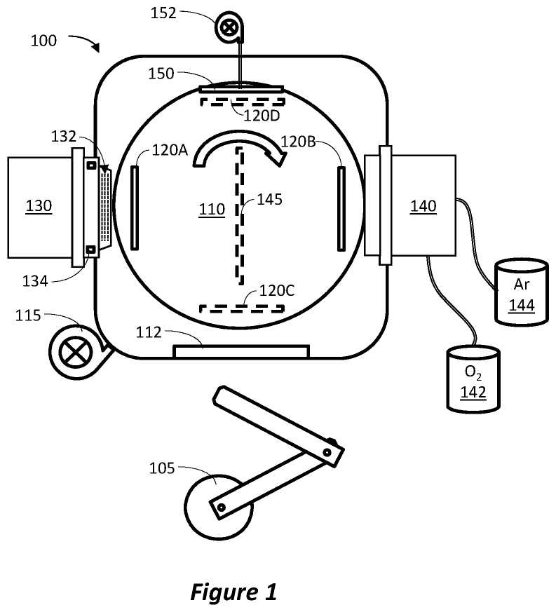

FIG. 1 is a schematic illustrating a top view of a DLC processing system according to an embodiment. The system of FIG. 1 may be used to deposit high density DLC coating on substrates. In this particular example, a single processing chamber 100 is used, having two processing modules. The interior of chamber 100 is maintained in vacuum by vacuum pump 115, generally to a level below 100 mPa or below 1000 mPa. A loader 105, e.g., a SCARA robot, loads substrates via gate valve 112 onto a substrate holder in the form of a turntable 110. In the example shown, two substrates 120A and 120B are positioned on the turntable 110, however, the turntable may be designed to carry only a single substrate or four or more substrates (as shown by broken-line 120C and 120D).

Processing chamber 100 has two processing modules attached on opposing walls thereof: module 130 is a deposition module and module 140 is an etch module. Optionally, a partition 145 is provided to block line-of-sight between the two processing modules. Deposition module 130 may be a sputter magnetron capable of producing a mix of carbon ions and neutrals. However, other modalities are possible for alternative carbon sources, including many variants of physical vapor deposition (PVD) and chemical vapor deposition (CVD). Etch module 140 may be a remote plasma source or an in-situ plasma source, wherein plasma is ignited and maintained by inductive or capacitive RF, microwave, etc.

Processing is initiated on a substrate by rotating the turntable 110 so as to place the substrate in front of etch module 140. The substrate is exposed to oxygen plasma containing oxygen radicals and ions so that it may be cleaned of remaining carbaceous grease that may remain on the substrate surface after pre-vacuum processing treatment. The turntable 110 is then rotated to place the substrate in front of the deposition module 130. If two substrates have been loaded, then at this time the second substrate is placed in front of the etch module 140 and is exposed to cleaning plasma as well. Meanwhile, deposition module 130 forms a minute amount of DLC coating on the substrate. In one example, the thickness of the deposited layer is from about 0.5 mg/m² to about 2 mg/m². Once the deposition is completed, the substrate is rotated back to the plasma module 140 (at the same time the second substrate that was cleaned is in front of the deposition module 130 and undergoes deposition). At this stage, the thin DLC carbon film is exposed to the ashing environment from the etch module 140 for a prescribed duration, wherein the remaining amount of film upon the surface is fractional but not zero in comparison to the thickness before the plasma treatment. Following this treatment, the resultant film has been enriched in tetrahedral bonded carbon sp^{a}, by ashing the graphitic sp² carbon. The turntable 110 then rotates again to form another DLC layer over the just etched layer. The process continues to cycle in this manner until the desired total thickness of the DLC layer is achieved.

In the embodiment of FIG. 1 two additional substrate positions are optionally included, shown in broken line as 120C and 120D. When only one or two substrate positions are included in the system, then at every cycle the turntable rotates 180 degrees. Conversely, when the system includes four positions, at each cycle the turntable rotates 90 degrees. This provides time for the substrates that were just processed by processing modules 130 and 140 to cool, while the other two substrates are being processed.

In FIG. 1, deposition source 130 may include acceleration grid array 132. The grid array may include a first grid biased with positive potential, a second grid biased with negative potential and a third grid held at ground potential. Grid array 132 applies directional energy to the ions toward the substrate. Also, the deposition source 130 may include a magnet array 134. Magnet array 134 may be used to enhance and confine the plasma within the source 130.

Also, in FIG. 1 etch source 140 is connected to oxygen gas source 142 to maintain oxygen-rich plasma for ashing the sp² carbon by chemical reaction. Optionally, the etch module 140 may also be connected to argon gas source 144. Argon may be used to ignite and maintain plasma. Also, argon plasma can be used during the cleaning of the substrate, as it physically sputters material from the surface of the substrate. Thus, in one embodiment argon plasma is used during cleaning cycle, while oxygen plasma is used during ashing cycle.

When the system of FIG. 1 has provisions for processing four substrates, the stations not having an etch or deposition module may be used for cooling the substrate in between processing. The cooling may be achieved either by simply the time laps in between processing or, if higher rate of cooling is needed, cooling plate 150 may be provided in close proximity to the substrate. The cooling plate 150 may be connected to a chiller 152 circulating in the cooling plate 150 cooling liquid, e.g., chilled water, liquid nitrogen, etc.

Conversely, the system of FIG. 1 may include provisions for processing four or more substrates, wherein a corresponding number of processing modules are arranged around the turntable. For example, if four substrates are used, then two deposition and two etch modules may be provided in an interlaced manner around the turntable, such that at each 90 degree turn a substrate is moved from a deposition module to an etch module or from an etch module to a deposition module. In this manner, all of the substrates are processed simultaneously. In a similar example, if the turntable is configured for eight substrates, then four deposition and four etch modules are arranged in an interlaced manner around the turntable, such that at every 45 degrees rotation, a substrate is moved from a deposition module to an etch module or from an etch module to a deposition module. In this manner, all of the eight substrates are processed simultaneously.

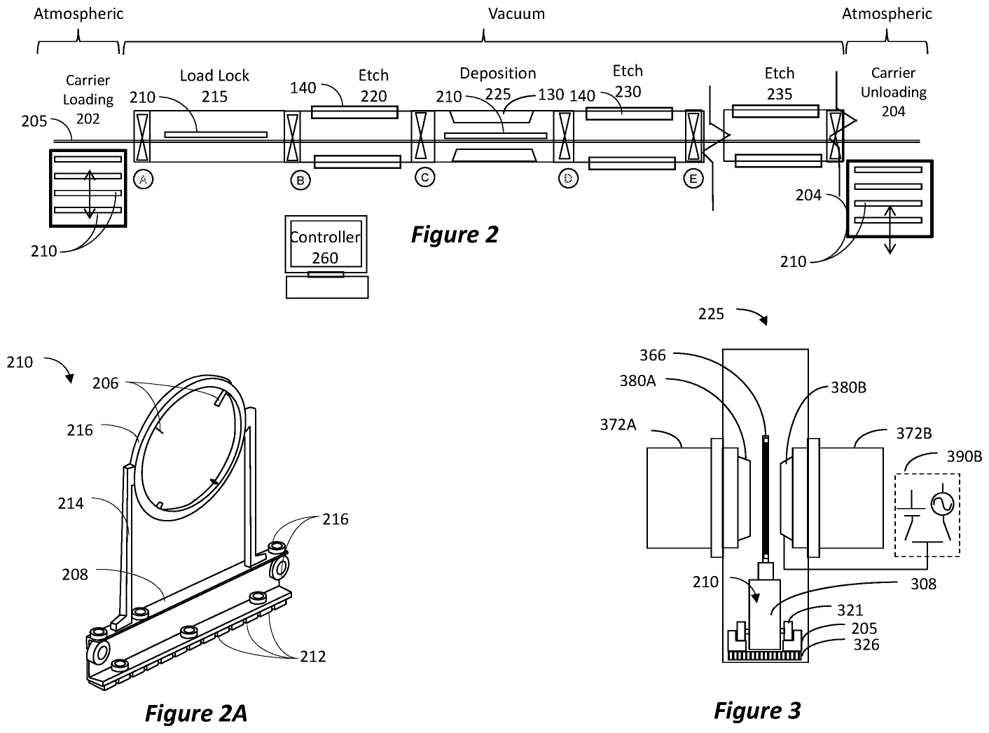

FIG. 2 illustrates an example for a linear system which may be used to form the high density DLC coating. In FIG. 2 a linear track 205 traverses the entire system and substrate carriers 210 ride on the linear track 205 while supporting one or a plurality of substrates. A carrier loading station 202 is used to load carriers 210 onto the linear track 205 in atmosphere. Then the carriers enter a loadlock 215, gate valve A is closed, and the loadlock is pumped to the required vacuum level. Gate valve B is then opened and the carrier moves into the first etch station 220 and gate valve B is closed. The substrate is then etched by etch source 140, so as to remove any contaminants and oxides from the surface of the substrate. In this particular example, both sides of the substrate are processed, although this need not necessarily be the case. Meanwhile, another carrier can be loaded into the loadlock and the required loadlock pumped to vacuum level.

Once the substrate has been sufficiently etched, gate valve C is opened, the carrier moves to the deposition module 225 and gate valve C is closed. At the same time, the carrier that was in the loadlock can be moved into the etch module 220, and another carrier loaded onto the loadlock 215. A deposition source 130 is then used to deposit a very thin layer of DLC coating on the substrate. In one example, the amount of the deposited layer is from about 0.5 mg/m² to about 2 mg/m². Once deposition is completed, the carrier is moved to etch module 230, and all carriers behind move one step and a new carrier loaded onto the loadlock. The just deposited layer is then etched so as to ash the graphitic sp² carbon.

As illustrated by the cut mark in FIG. 2, the system includes a plurality of etch modules and a plurality of deposition modules arranged in an interlaced manner, terminating in an etch module 235. From the last etch module 235 the carriers exit through unloading loadlock (not shown) onto a carrier unloading module 204.

FIG. 2A illustrates an example of a substrate carrier that can be used in the embodiment of FIG. 2, according to one embodiment. As illustrated in FIG. 2A, the base 208 of carrier 210 has wheels 216, which engage the linear track 205 in the system (shown in FIG. 3). The base 208 also incorporates part of a magnetic transport system. Namely, in this embodiment, a magnetic transport mechanism is implemented as a lineal motor used to linearly transport the carrier between chambers and into and out of the system. The linear motor may be of a reluctance type. To interact with the linear motor, magnetic material, magnets, or both (212) are positioned on the base 208. In one embodiment, elements 212 are made of magnetic material. In other embodiment elements 212 are individual magnets. In yet other embodiment elements 212 are individual magnets attached to magnetic material. As described herein, the use of linear motor for the transport of carriers largely eliminates the need for enhanced friction to enable rapid acceleration and deceleration control.

Substrate support arms 214 are attached to the base 208, leading to frame 216. Frame 216 includes clips 206 which support the substrate at peripheral circumference thereof. This enables double sided processing without contacting either surface of the substrate. The support arms 214 and frame 216 are made as thin as possible, thereby enabling placing the cooling plates 130 and 140 very close to the substrate to efficiently remove heat from the substrate.

FIG. 3 illustrates a cross section of a processing module, e.g., deposition module 225, which is fitted with two sputtering sources 372A and 372B, according to one embodiment. As noted, if only one surface is to be coated, then only one of sputtering source 372A and 372B is mounted. Also, the etch modules are constructed in a similar manner, except that sputtering sources 372A and 372B are replaced by plasma sources. Substrate 366 is shown mounted vertically onto carrier 210. Carrier 210 may have the same or similar construction to the carrier illustrated in FIG. 2A. For example, base 308 has wheels 321, which ride on linear track 205. It is noted that the reverse can also be implemented, i.e., the carrier may have linear tracks which ride on wheels situated in a straight line in the chamber (not shown). The wheels 321 may be magnetic, in which case the linear track 205 may be made of paramagnetic material. In this embodiment the carrier is moved by linear motor 326, although other motive forces and/or arrangements may be used. Depositions source 372A is shown mounted onto one side of the chamber 225, while deposition source 372B is mounted on the other, opposite, side of the chamber 225. The carrier is positioned between deposition sources 372A and 372B, such that deposition is performed on both surfaces of the substrate.

As shown in FIG. 3, sputter sources 372A and 372B generate ions for deposition onto the substrate 366. The ions are generated by sustaining plasma of, e.g., argon gas, within the sputtering source, such that the argon ions in the plasma sputter targets made of the material to be deposited onto the substrate 366. When atoms of the material to be deposited are ejected from the target they are ionized by electrons accelerated within the plasma region. The ions are then directed towards the substrate. According to embodiments of the invention, the energy of the ions may be increased or reduced prior to impinging on the substrate by a field generated just ahead of the substrate. In the embodiment illustrated in FIG. 3, the field is generated by biasing shutters 380A and 380B, which are biased by an RF or DC power source, as exemplified by power source 390B.

In the embodiments disclosed, when using sputtering for the deposition modules, the source may operate in a variety of power modalities, including DC, pulsed DC (e.g., pulsed at 0-300 kHz and 0-3 μs reverse time), and RF (e.g., at frequencies of from 2 to 13.56 GHz). The sputtering is performed by maintaining argon plasma within the sputtering source. The plasma is maintained at argon pressure of from 100 mPa to 1000 mPa. It is believed that lower pressure leads to higher tetrahedral sp³ carbon film formation. Therefore, in some embodiments the argon pressure is maintained below 100 mPa. Graphite target is used as the carbon source for the carbon film formation.

In disclosed embodiments, a method for forming a diamond-like carbon (DLC) coating is provided, comprising alternatingly performing a deposition process and an ashing process on a substrate a determined number of times, wherein during the deposition process the method proceeds by forming a layer of DLC which includes graphitic sp² carbon and tetrahedral sp³ carbon, and during the ashing process the method proceeds to selectively etching the graphitic sp² carbon, wherein the determine number of time is determined to result in a designated overall thickness of the DLC coating.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

1. A method for forming a diamond-like carbon (DLC) coating on an article, comprising: alternatingly performing a deposition process and an ashing process on the article a determined number of times, wherein during the deposition process the method proceeds by forming on the article a layer of DLC which includes graphitic sp² carbon and tetrahedral sp³ carbon, and during the ashing process the method proceeds by selectively etching the graphitic sp² carbon, wherein the determine number of time is configured to result in a designated overall thickness of the DLC coating.

2. The method of claim 1, wherein the deposition process is performed by sustaining plasma in a sputtering source.

3. The method of claim 2, wherein sustaining plasma includes maintaining an argon environment within the sputtering source at a pressure of less than 1000 mPa.

4. The method of claim 1, further comprising a preclean step of etching the article prior to alternatingly performing the deposition process and the ashing process.

5. The method of claim 4, wherein etching the article comprises immersing the article in plasma maintained by at least one of argon and oxygen gas.

6. The method of claim 1, wherein selectively etching is performed by contacting the article with oxygen radicals.

7. The method of claim 6, wherein contacting the article with oxygen radicals is performed by maintaining oxygen plasma in an etch module.

8. The method of claim 6, wherein contacting the article with oxygen radicals comprises immersing the article in oxygen plasma.

9. The method of claim 1, wherein alternatingly performing a deposition process and an ashing process comprises loading the article onto a turntable and rotating the turntable such that at each complete revolution of the turntable the article is passed at least once through a deposition module and through an etch module.

10. The method of claim 1, wherein forming on the article a layer of DLC comprises depositing on the article an amount of from 0.5 mg/m² to 2 mg/m².

11. A system for forming a diamond-like carbon (DLC) coating, comprising:
a turntable for supporting at least one article;
at least one carbon deposition module having a graphite target and positioned on an arc of the turntable;
at least one ashing module positioned on an arc of the turntable;
an argon gas source delivering argon gas to the at least one carbon deposition module; and,
an oxygen gas source delivering oxygen gas to the ashing module.

12. The system of claim 11, comprising one carbon deposition module and one ashing module positioned at 180 degrees separation around the turntable.

13. The system of claim 11, comprising a plurality of carbon deposition modules and a plurality of ashing module arranged around the turntable in an interlaced manner.

14. A system for forming a diamond-like coating (DLC), comprising:
a loadlock;
a linear array of processing modules;
a linear track traversing the loadlock and the linear array of processing modules;
a plurality of substrate carriers transported on the linear track;
wherein the linear array of processing module comprises a plurality of sputtering modules each having a graphite target and a plurality of etching modules each connected to an oxygen source, wherein the plurality of sputtering modules and plurality of etching modules are interlaced to form the linear array.

15. The system of claim 11, wherein each sputtering module is attached directly to two etch modules, one on each side thereof, and each etch module is directly attached to at least one sputtering module.

16. A method for forming a diamond-like carbon (DLC) coating on a substrate, comprising:
loading the substrate onto a substrate holder;
repeatedly transporting the substrate between a carbon deposition module and a carbon etching module a predetermined number of times, and at the carbon deposition module forming a layer of carbon on the substrate and at the etching module partially etching the layer of carbon;
wherein the predetermined number of times is configured to result in a designated total thickness of DLC coating.

17. The method of claim 16, wherein forming a layer of carbon comprises depositing amount of carbon of from 0.5 mg/m² to 2 mg/m².

18. The method of claim 17, wherein partially etching the substrate comprises immersing the substrate in oxygen plasma.

19. The method of claim 16, wherein transporting the substrate comprises rotating a turntable.

20. The method of claim 16, wherein transporting the substrate comprises transporting a substrate carrier on a linear track.
